(19) United States
(12) Patent Application Publication
(10) Pub. No.: US 2026/0031115 A1
(43) Pub. Date: Jan. 29, 2026

(54) ROW AND COLUMN ACCESS OF MATRICES STORED IN MEMORY

(71) Applicant: Micron Technology, Inc., Boise, ID (US)

(72) Inventor: Glen E. Hush, Boise, ID (US)

(21) Appl. No.: 19/268,211

(22) Filed: Jul. 14, 2025

Related U.S. Application Data
(60) Provisional application No. 63/676,349, filed on Jul. 27, 2024.

(51) Int. Cl. G11C 7/10; G11C 8/10

(52) U.S. Cl. CPC G11C 7/1012; G11C 7/1069; G11C 8/10

(57) ABSTRACT

A crossbar and/or multiplexors (MUXs) of a memory device can be utilized to provide row and column access of a matrix stored in an array of the memory device. The crossbar can couple input lines to the crossbar to output lines from the crossbar in a particular configuration, where the output lines couple the crossbar to the array. The crossbar can receive data values of a matrix via the input lines. The crossbar can also provide the data values to the array via the output lines. The particular configuration allows the data values provided to the array to be sensed as columns of the data values of the matrix and rows of the data values of the matrix.

### PRIORITY INFORMATION

This application claims the benefit of U.S. Provisional Application No. 63/676,349, filed on Jul. 27, 2024, the contents of which are incorporated herein by reference.

### TECHNICAL FIELD

The present disclosure relates generally to memory, and more particularly to apparatuses and methods associated with accessing rows and columns of matrices stored in memory.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram of a processing unit in accordance with a number of embodiments of the present disclosure.

FIG. 3A is a block diagram of a crossbar in a first configuration in accordance with a number of embodiments of the present disclosure.

FIG. 3B is a block diagram of a crossbar in a second configuration in accordance with a number of embodiments of the present disclosure.

FIG. 3C is a block diagram of a crossbar in a third configuration in accordance with a number of embodiments of the present disclosure.

FIG. 3D is a block diagram of a crossbar in a fourth configuration in accordance with a number of embodiments of the present disclosure.

FIG. 3E is a block diagram of a crossbar in a fifth configuration in accordance with a number of embodiments of the present disclosure.

FIG. 3F is a block diagram of a crossbar in a sixth configuration in accordance with a number of embodiments of the present disclosure.

FIG. 3G is a block diagram of a crossbar in a seventh configuration in accordance with a number of embodiments of the present disclosure.

FIG. 3H is a block diagram of a crossbar in an eighth configuration in accordance with a number of embodiments of the present disclosure.

FIG. 4A is a block diagram of a crossbar receiving data values having different addresses in accordance with a number of embodiments of the present disclosure.

FIG. 4B is a block diagram of a crossbar receiving data values having different addresses in accordance with a number of embodiments of the present disclosure.

FIG. 4C is a block diagram of a crossbar receiving data values having different addresses in accordance with a number of embodiments of the present disclosure.

FIG. 4D is a block diagram of a crossbar receiving data values having different addresses in accordance with a number of embodiments of the present disclosure.

FIG. 4E is a block diagram of a crossbar receiving data values having different addresses in accordance with a number of embodiments of the present disclosure.

FIG. 4F is a block diagram of a crossbar receiving data values having different addresses in accordance with a number of embodiments of the present disclosure.

FIG. 4G is a block diagram of a crossbar receiving data values having different addresses in accordance with a number of embodiments of the present disclosure.

FIG. 4H is a block diagram of a crossbar receiving data values having different addresses in accordance with a number of embodiments of the present disclosure.

FIG. 5 illustrates an example flow diagram of a method for accessing rows and columns of data values of a matrix stored in a memory device in accordance with a number of embodiments of the present disclosure.

FIG. 6 illustrates an example machine of a computer system within which a set of instructions, for causing the machine to perform any one or more of the methodologies discussed herein, can be executed.

### DETAILED DESCRIPTION

The present disclosure includes apparatuses and methods related to accessing rows and columns of matrices stored in memory. A memory device can include an array of memory cells coupled to a crossbar. The crossbar can couple the input lines to the crossbar to output lines of the crossbar in a particular configuration. The output lines can couple the crossbar to the array. The crossbar can receive data values of a matrix from input lines. The crossbar can provide the data values to the array based on the particular configuration of the crossbar that is different from the input lines. The coupling of the input lines to the output lines in the particular configuration can allow the data values to be sensed (e.g., read) as columns of the data values and rows of the data values of the matrix.

In previous approaches, a matrix of data values can be stored in a row of an array of memory cells such that each row of data values of the matrix can be stored in a row of a same sub-array. Each of the columns of a sub-array can be coupled to a same sense amplifier. To access an entire row of the sub-array, the row of the sub-array can be activated and each of the columns of the sub-array can be activated sequentially. The sequential activation of each of the columns of the sub-array to access a row of the matrix can cause a delay to access the row of the matrix as compared to accessing a column of the matrix. A column of the matrix can be accessed by activating a row of each of the sub-arrays and a same column in each of the sub-arrays concurrently. Concurrently activating a same column in each of the sub-arrays and the row of each of the sub-arrays to access a column of the matrix can be faster than sequentially activating columns of a same sub-array as is used to access a row of the matrix.

As used herein, a matrix is a grouping of data values organized into rows and columns where each data value has an order in a row and a column. For example, a first data value of a matrix can be a first data value in a first row and a first data value in a first column.

In order to address these and other deficiencies of previous approaches, embodiments of the present disclosure allow for data values of a matrix to be stored in an array of memory cells such that columns of data values of the matrix and/or rows of data values of the matrix can be accessed (e.g., retrieved) in a same amount of time. The data value of the matrix can be stored in an array such that data values of a row of a matrix are stored in different sub-arrays using different addresses. For example, a first data value of a row of a matrix can be stored in a first sub-array using a first address, a second data value of the row of the matrix can be stored in a second sub-array using a second address, a third data value of the row of the matrix can be stored in a third sub-array using a third address. Storing each data values of a row of a matrix in different sub-arrays using different addresses allows the data values of a row to be sensed and data values of a column of the matrix to be sensed in a same amount of time.

For example, data values of a column of a matrix can be sensed by coupling input lines to output lines using coupling circuitry (e.g., a crossbar) having different configurations. Data values of a row of a matrix can be sensed by reading different addresses of different sub-arrays at the same time. For example, a first address of a first sub-array and a second address of a second sub-array can be sensed at the same time to sense data values of a row of a matrix.

In various instances, it may be beneficial to have the ability to retrieve data values of a row and data values of a column of a matrix in a same amount of time. For example, matrix-vector multiplication operations can be performed by multiplying data values of columns of a matrix using data values of a vector. In other examples, matrix-vector multiplication operations can be performed by multiplying data values of rows of the matrix using data values of a vector.

Matrix-vector multiplication operations can be performed in the context of artificial intelligence (AI). As used herein, AI refers to the ability to improve an apparatus through “learning” such as by storing patterns and/or examples which can be utilized to take actions at a later time. Deep learning refers to a device's ability to learn from data provided as examples. Deep learning can be a subset of AI. Neural networks, among other types of networks, can be classified as deep learning. A neural network can include an artificial neural network (ANN) among other types of neural networks. Improving the efficiency at which ANNs are executed can improve a function of a memory device executing the ANN. The efficiency at which the ANN can be executed can be improved by providing rows and columns of a matrix to the ANN for performing operations.

As used herein, “a number of” something can refer to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

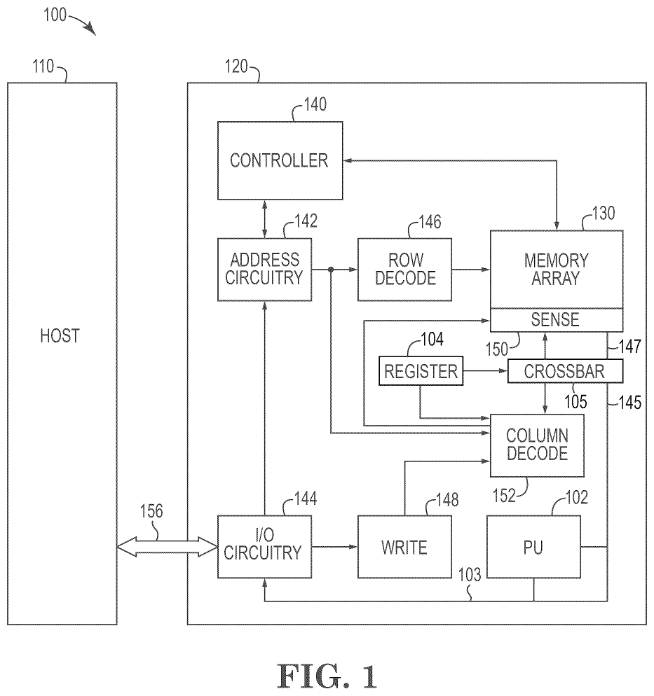

FIG. 1 is a block diagram of an apparatus in the form of a computing system 100 including a memory device 120 in accordance with a number of embodiments of the present disclosure. As used herein, a memory device 120, a memory array 130, and/or host 110 might also be separately considered an “apparatus.”

In this example, system 100 includes a host 110 coupled to memory device 120 via an interface 156. The computing system 100 can be a personal laptop computer, a desktop computer, a digital camera, a mobile telephone, a memory card reader, or an Internet-of-Things (IoT) enabled device, among various other types of systems. Host 110 can include a number of processing resources (e.g., one or more processors, microprocessors, or some other type of controlling circuitry) capable of accessing memory 120. The system 100 can include separate integrated circuits, or both the host 110 and the memory device 120 can be on the same integrated circuit. For example, the host 110 may be a system controller of a memory system comprising multiple memory devices 120, with the system controller 110 providing access to the respective memory devices 120 by another processing resource such as a central processing unit (CPU).

In the example shown in FIG. 1, the host 110 is responsible for executing an operating system (OS) and/or various applications that can be loaded thereto (e.g., from memory device 120 via controller 140). The host 110 can provide access commands and/or security mode initialization commands to a memory device via the interface 156.

For clarity, the system 100 has been simplified to focus on features with particular relevance to the present disclosure. The memory array 130 can be a DRAM array, SRAM array, STT RAM array, PCRAM array, TRAM array, RRAM array, NAND flash array, and/or NOR flash array, for instance. The array 130 can comprise memory cells arranged in rows coupled by access lines (which may be referred to herein as word lines or select lines) and columns coupled by sense lines (which may be referred to herein as digit lines or data lines). Although a single array 130 is shown in FIG. 1, embodiments are not so limited. For instance, memory device 120 may include a number of arrays 130 (e.g., a number of banks of DRAM cells).

The memory device 120 includes address circuitry 142 to latch address signals provided over an interface 156. The interface can include, for example, a physical interface employing a suitable protocol (e.g., a data bus, an address bus, and a command bus, or a combined data/address/command bus). Such protocol may be custom or proprietary, or the interface 156 may employ a standardized protocol, such as Peripheral Component Interconnect Express (PCIe), Gen-Z, CCIX, or the like. Address signals are received and decoded by a row decoder 146 and a column decoder 152 to access the memory array 130. Data can be read from memory array 130 by sensing voltage and/or current changes on the sense lines using sensing circuitry 150. The sensing circuitry 150 can comprise, for example, sense amplifiers that can read and latch a page (e.g., row) of data from the memory array 130. The I/O circuitry 144 can be used for bi-directional data communication with host 110 over the interface 156. The read/write circuitry 148 is used to write data to the memory array 130 or read data from the memory array 130. As an example, the circuitry 148 can comprise various drivers, latch circuitry, etc.

The controller 140 decodes signals provided by the host 110. These signals can include chip enable signals, write enable signals, and address latch signals that are used to control operations performed on the memory array 130, including data read, data write, and data erase operations. In various embodiments, the controller 140 is responsible for executing instructions from the host 110. The controller 140 can comprise a state machine, a sequencer, and/or some other type of control circuitry, which may be implemented in the form of hardware, firmware, or software, or any combination of the three.

In various instances, the controller 140 can receive signals provided by the host 110 including signals requesting operations to be performed by a processing unit (PU) 102. For example, the controller 140 can provide a signal requesting that a matrix-vector multiplication operation be performed to the PU 102. The controller 140 can receive the signal from the host 110 and can cause a matrix of data values and a vector of data values to be sensed (e.g., read) from the memory array 130 and provided to the PU 102. As used herein, the PU 102 can include hardware, firmware, and/or software for performing operations using data provided by the memory array 130. For example, the PU 102 can perform multiplication operations in accordance with embodiments of the present disclosure. The PU 102 can multiply a matrix of data values with a vector of data values. As used herein, a data value is a number that can be used to perform operations such as multiplication operations.

In various examples, the sensed data values can be provided from the sensing circuitry 150 to a crossbar 105. The sensing circuitry 150 and/or the crossbar 105 can be utilized to provide data values of columns of a matrix and data values of rows of the matrix to the PU 102. The sensing circuitry 150 and/or the crossbar 105 can also provide data values of columns of a matrix and data values of rows of the matrix to different components of the memory device 120 and/or externally from the memory device 120.

For example, the column decoder 152 can communicate with the sensing circuitry 150 to cause the sensing circuitry to provide data values of rows of the matrix. The crossbar 105 can be configured by the column decoder 152 to provide data values of columns of the matrix by connecting lines 147 that couple the sensing circuitry 150 to the crossbar 105 to lines 145 that couple the crossbar 105 to the I/O circuitry 144. In various instances, the lines 145 can be referred to as output lines, and lines 147 can be referred to as input lines. As used herein, the crossbar 105 can include hardware, software, and/or firmware configured to couple the lines 147 to the lines 145 in a particular configuration.

The crossbar 105 and the sensing circuitry 150 can be coupled to a number of registers 104. The registers 104 can store data which can be used to determine whether data values of columns or data values of rows of a matrix are being sensed. For example, the registers 104 can store a mode of the memory device 120. The registers 104 can store a first mode and/or a second mode. The first mode can indicate that the data values being accessed or stored are a column of the matrix. The second mode can indicate that the data values being accessed are a row of the matrix. The function of the sensing circuitry 150 and/or the crossbar 105 can change based on whether data values of columns or data values of rows are being sensed (e.g., based on the mode of memory device 120).

The columns and/or rows of a matrix can be provided to the PU 102. The PU 102 can utilize lines 145 to receive the data values of a matrix and data values of a vector and to output (e.g., provide) a result vector of data values (e.g., the result of the multiplication operations). The result vector of data values can be stored back to the memory array 130 and/or can be provided to the host 110. Utilizing the same lines 145 to read data from the memory array 130, to provide data to the PU 102, and/or to provide data from the PU 102 can allow for the PU 102 to be added to the memory device 120 without substantially adding to the die area of the memory device 120. For example, the PU 102 can be added to the memory device 103 by increasing a die size of the memory device 120 by 1-3% as compared to solutions that do not include the memory device 103. The 1-3% increase in die size is compared to solutions in which the PU 102 is added to the memory device 103 such that the PU 102 does not receive data and/or provide data via the lines 145.

In various examples, the PU 102 can receive columns of data values of a matrix and data values of a vector from the memory array 130 to perform the matrix-vector multiplication operation. The data values of the matrix can be stored in the memory array 130 such that the data values organized in columns can be sensed as opposed to sensing rows of the memory array 130. In other examples, the PU 102 can receive rows of data values of the matrix.

In various instances, the controller 140 can cause data values received from the host 110 to be organized and stored in the memory array 130 such that columns of a matrix or rows of the matrix can be retrieved from the array 130. As used herein, the array 130 can include sub-arrays. Sub-arrays can denote memory cells of the array 130 that are separated either physically or logically from memory cells of different sub-arrays of the array 130.

Providing columns of data values to the PU 102 allows the PU 102 to perform operations on the columns of data value such that the results of the matrix-vector multiplication operation are stored in accumulators of MAC units of the PU 102 without performing additional operations to combine the results into a result vector. Providing the result vector of the matrix-vector multiplication operation utilizing the lines 145 and storing the result vector in accumulators of the multiply-accumulate (MAC) units of the PU 102 allows for the result vector to be generated and provided to the lines 145 in the same amount of time as is used to sense the matrix and/or the vector from the memory array 130.

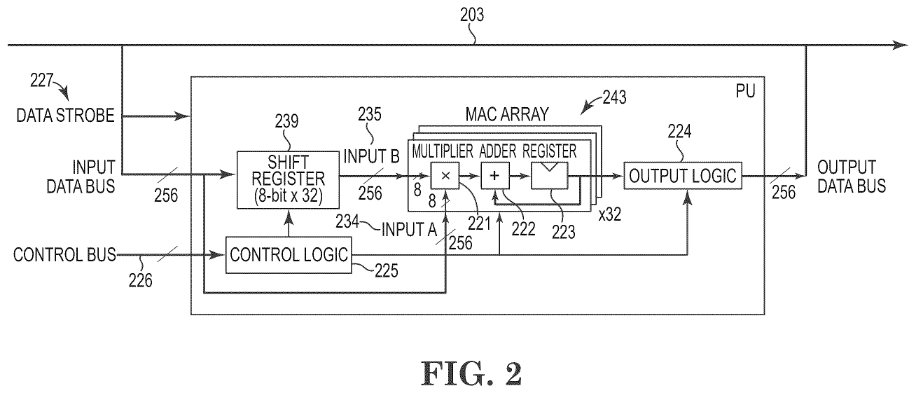

FIG. 2 is a block diagram of a PU 202 in accordance with a number of embodiments of the present disclosure. The PU 202 is coupled to the I/O lines 203. The PU 202 includes the register(s) 239, the MAC units 243, control logic 225, and output logic 224. The PU 202 can receive a data strobe signal 227, a control signal 226, and input signals.

The input signals can provide data values 234, 235 of a matrix and/or a vector. The data values of the matrix and/or the vector can be provided sequentially. For example, the data values (e.g., data value 235) of a vector can be stored in the register 239. The data values (e.g., data value 234) of a matrix can be provided directly to the MAC units 243 or can be stored in a different register (not shown) prior to being provided to the MAC units 243. The example of FIG. 2 does not include registers to store the data values of the matrix. Other examples can include registers to store the data values of the matrix.

In the example of FIG. 2 a width of the input data bus can be 256-bits. In such an example where the vectors to be operated on include 8 bits, 32 8-bit vectors can be provided in a single 256-bit data chunk. The data values of the matrix can also be provided to the PU in 256-bit chunks. Each of the data values of the vector and the matrix can include 8-bits. The register(s) 239 (Shift Register) can provide each of the data values replicated to fill the 256-bits provided from the registers 239 to the MAC units 243. For example, a first data value (V0) can be replicated thirty-two times to generate 256-bits. Each of the MAC units 243 can receive the same 8-bits (V0) from the 256-bits.

The MAC units 243 can receive the data values from the registers 239 and the data values of the matrix from the I/O lines 203. The MAC units 243 can include multiply circuitry 221, adder circuitry 222, and registers 223. The MAC unit 243 can utilize the multiply circuitry 221, adder circuitry 222, and registers 223 to multiply and accumulate the data values of the vector and the data values of the matrix. The output logic 224 can be controlled to output the output vector. The output vector can be provided to the I/O lines 203.

The data strobe signal 227 can be utilized to provide timing signals for latching the data values in the registers 239 and for performing the operations of the MAC units 243. The data strobe signal 227 can also be used to determine when to forward the output vector to the I/O lines 203.

The control signal 226 can provide the control logic 225 with the information needed to perform a number of operations. For example, the control signal 226 can be utilized to indicate to the registers 239 that the data values should be replicated and/or shifted within the registers 239. The control signal 226 can cause the control logic 225 to indicate to the output logic 224 when to forward the output vector. The data strobe signal 227 and/or the control signal 226 can be provided by control circuitry of the memory device.

The control signals 226 can be used to load the register 239, forward (e.g., read and/or load) the output vector, and provide data values to the MAC unit 243. The control signals 226 can also be used to indicate that the registers 239 should be shifted.

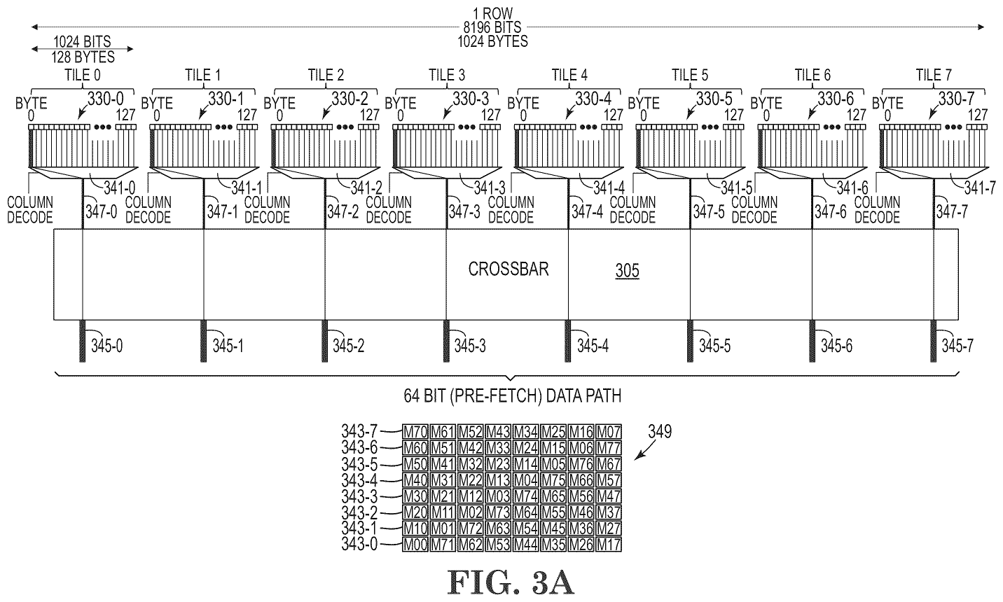

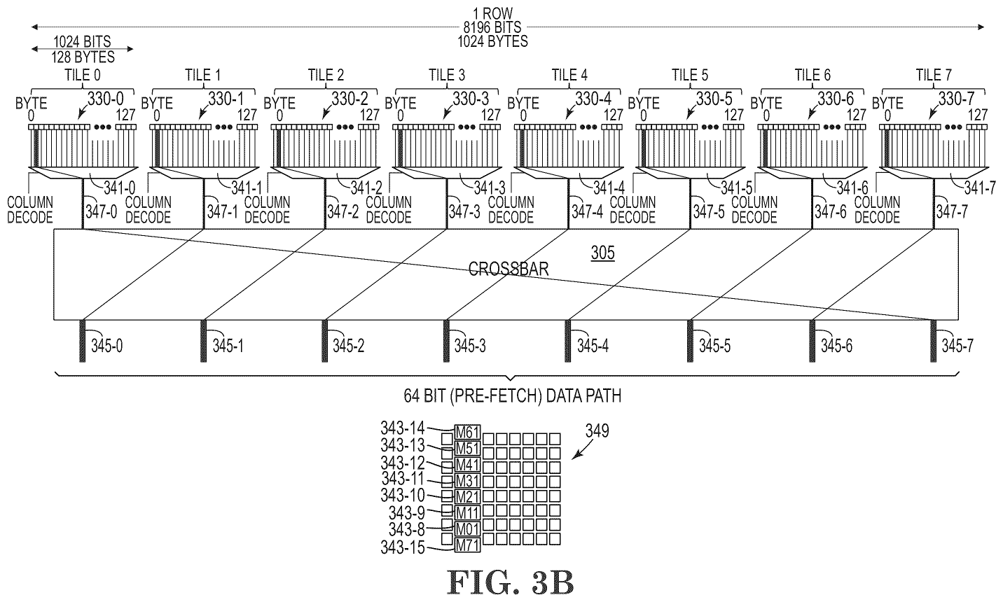

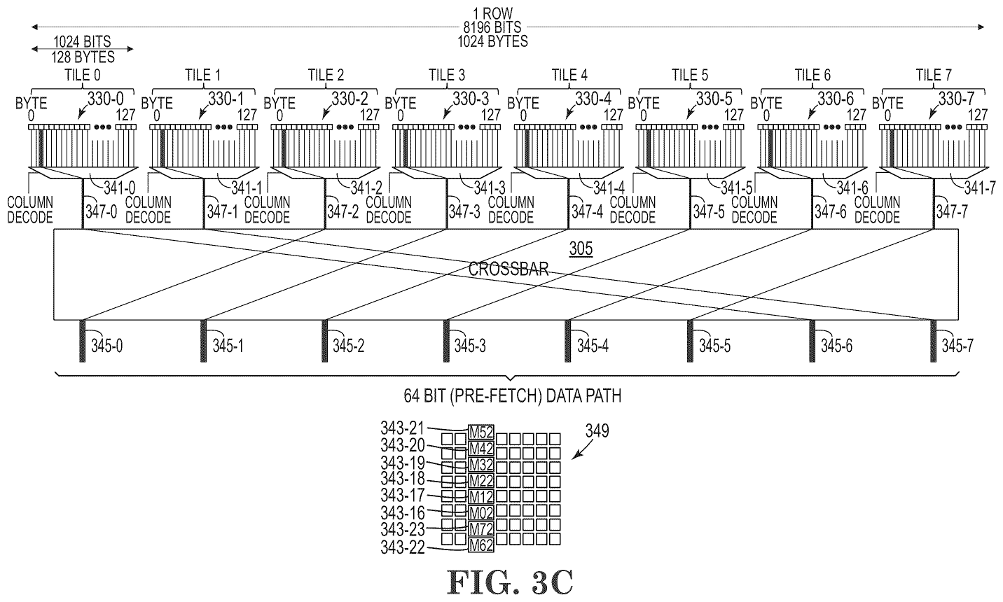

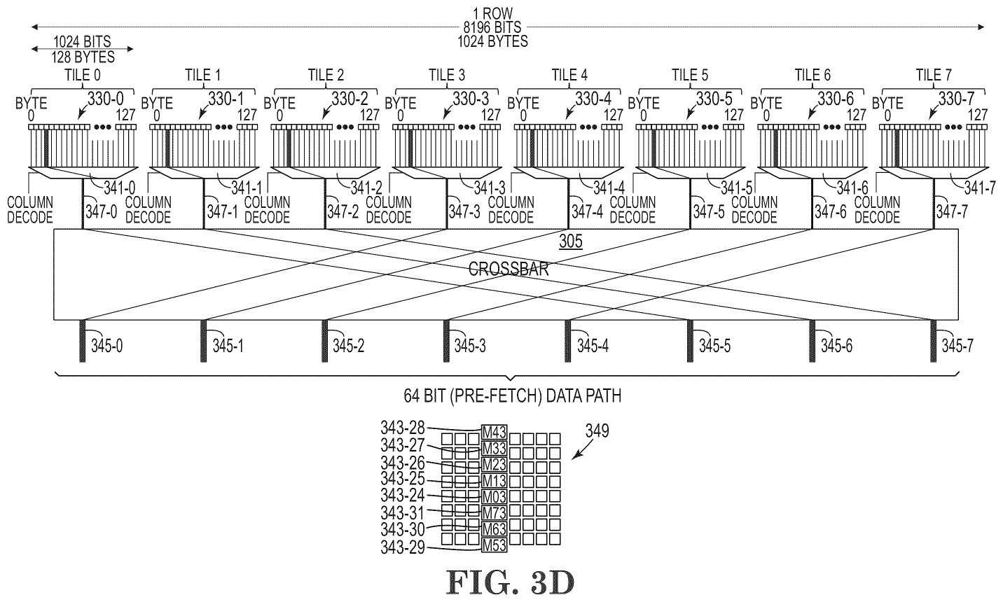

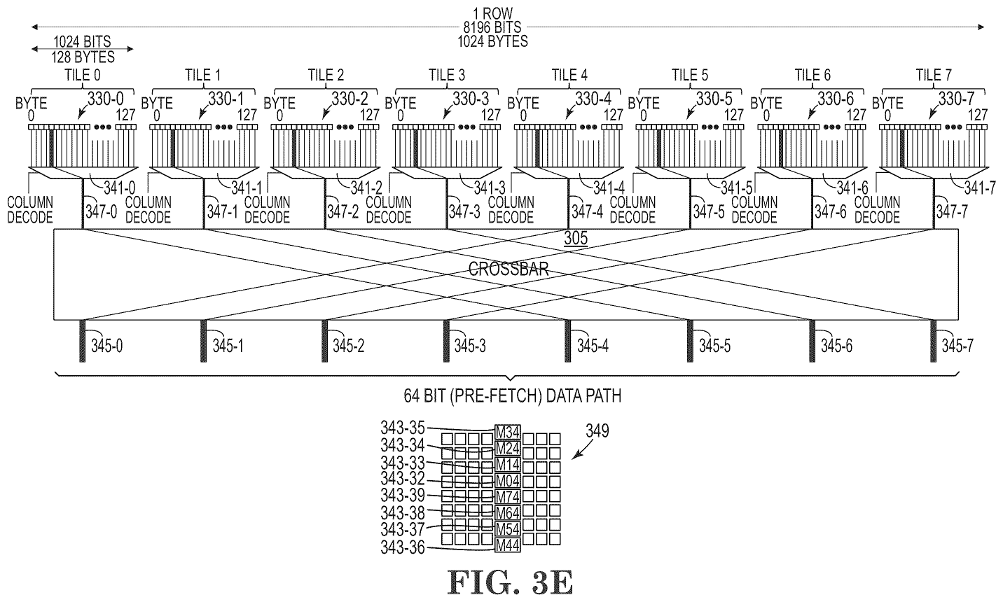

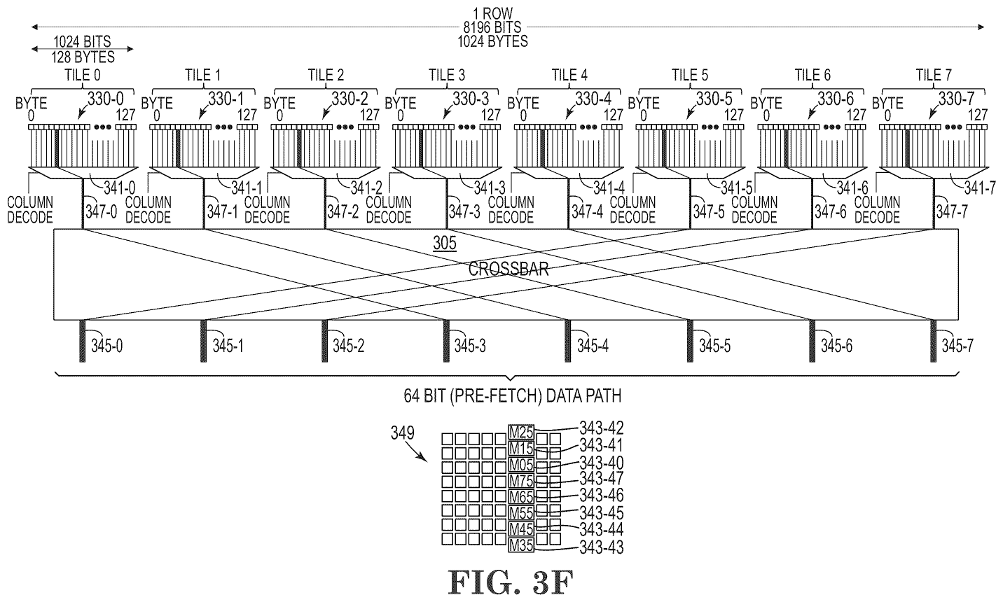

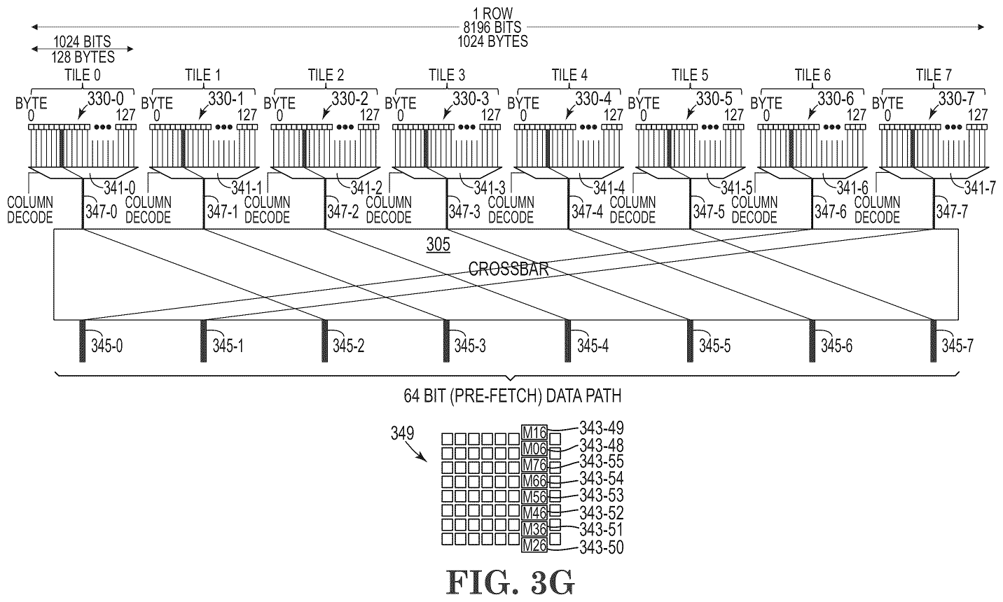

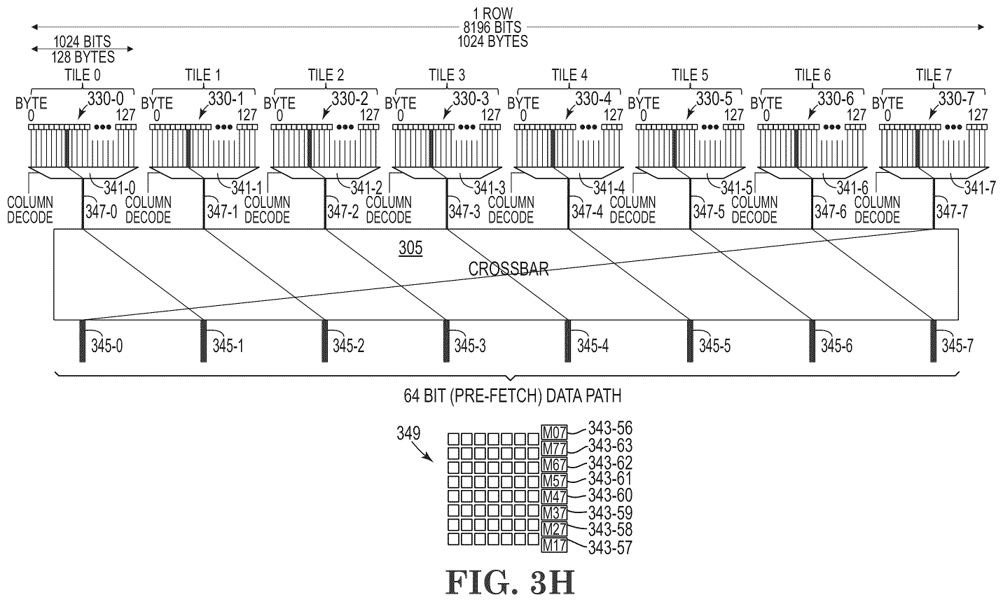

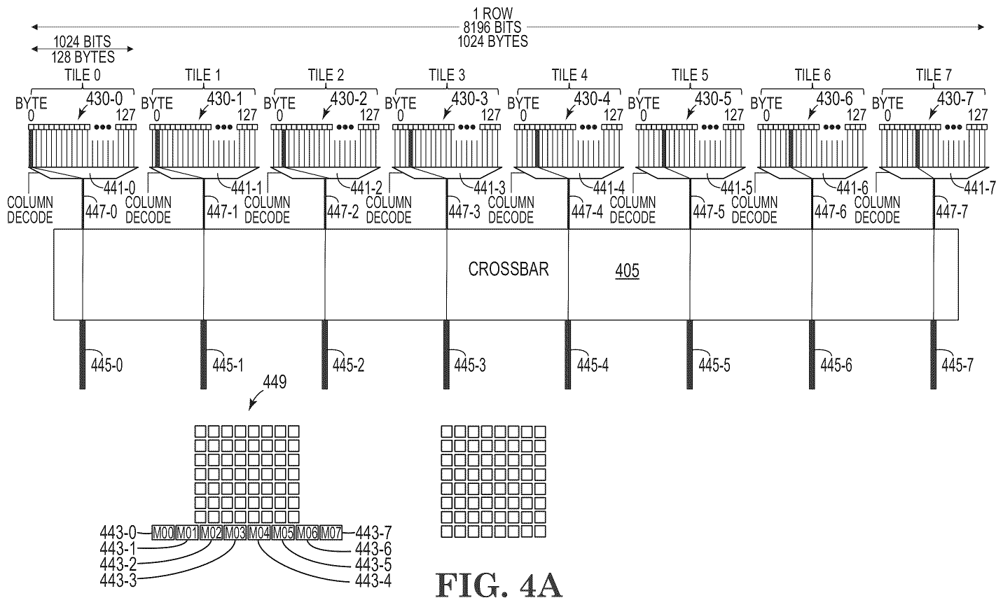

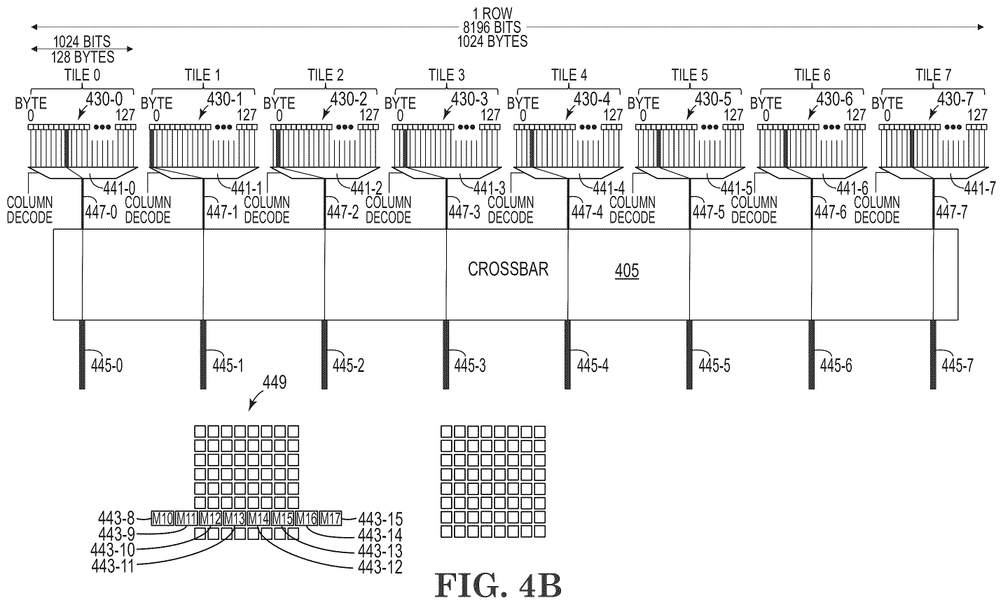

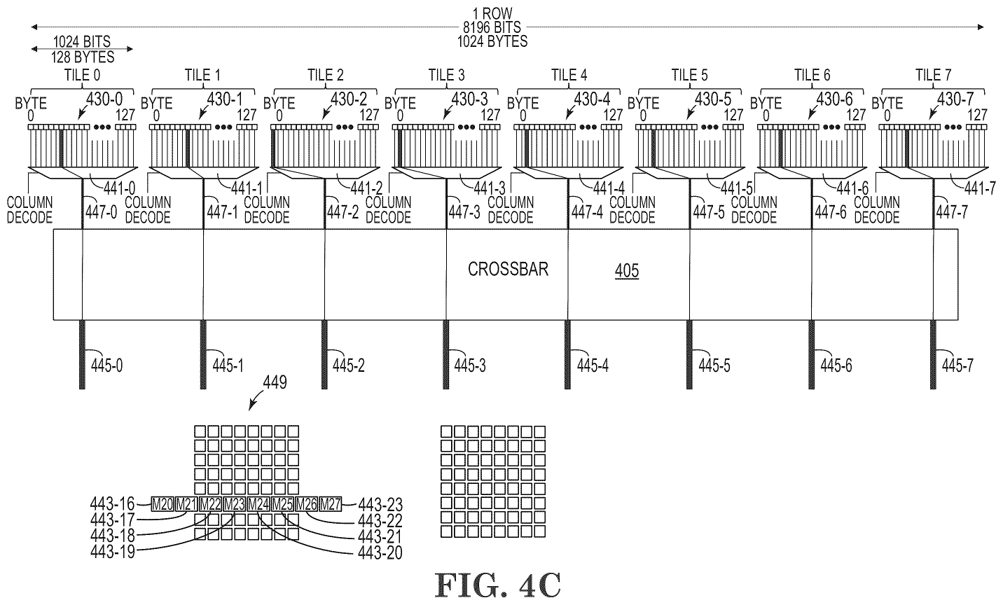

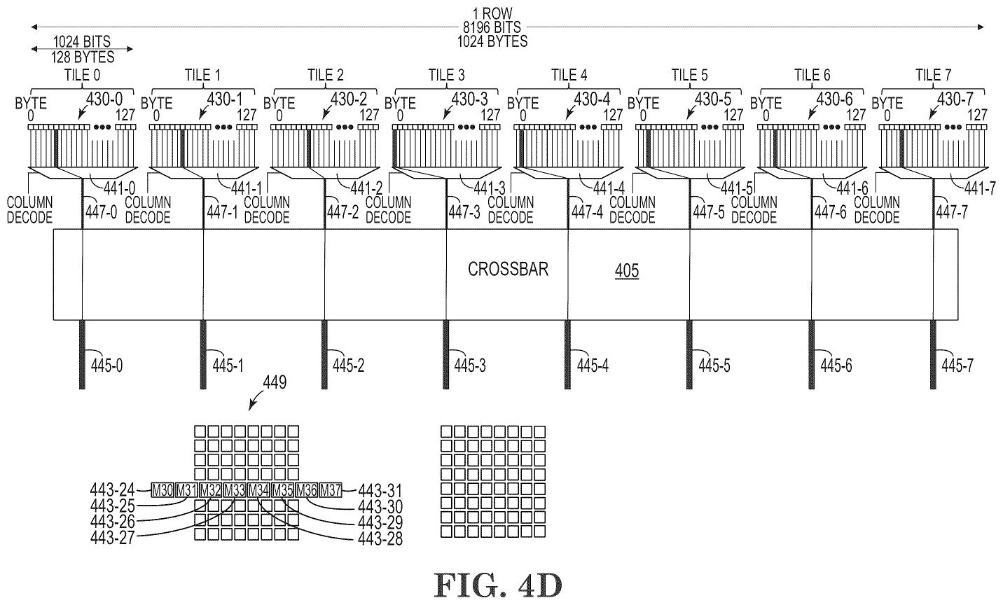

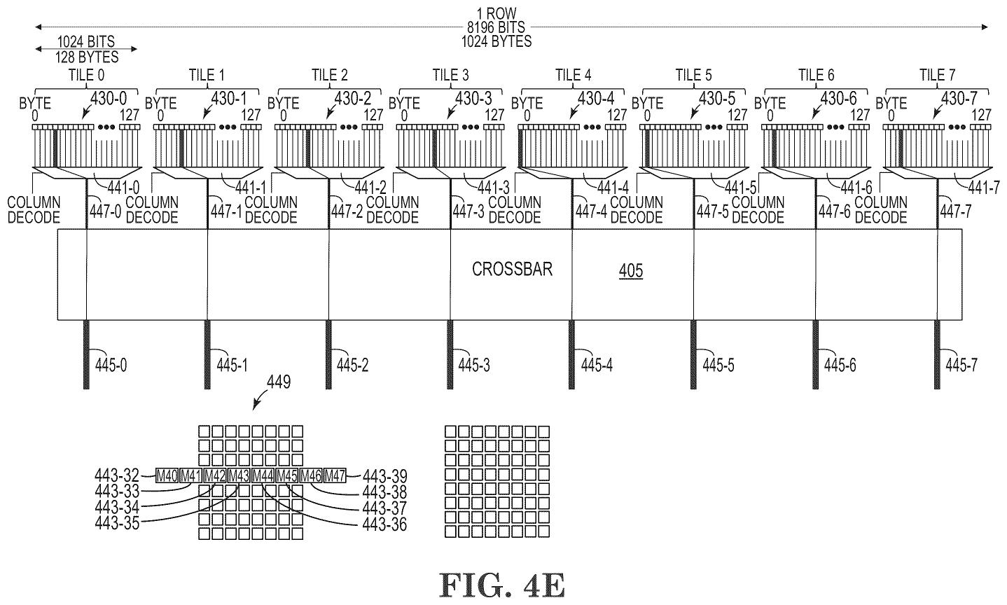

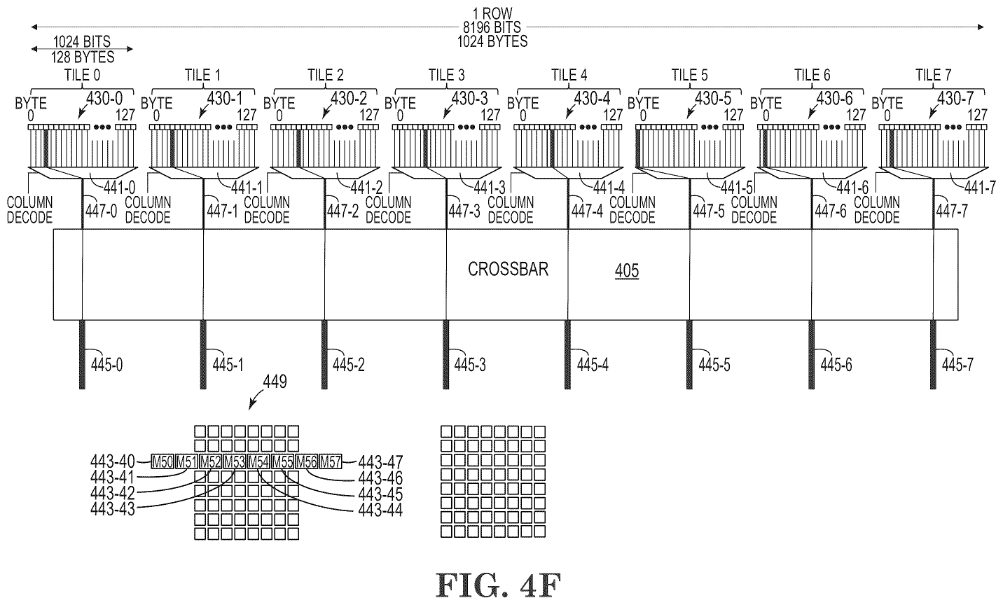

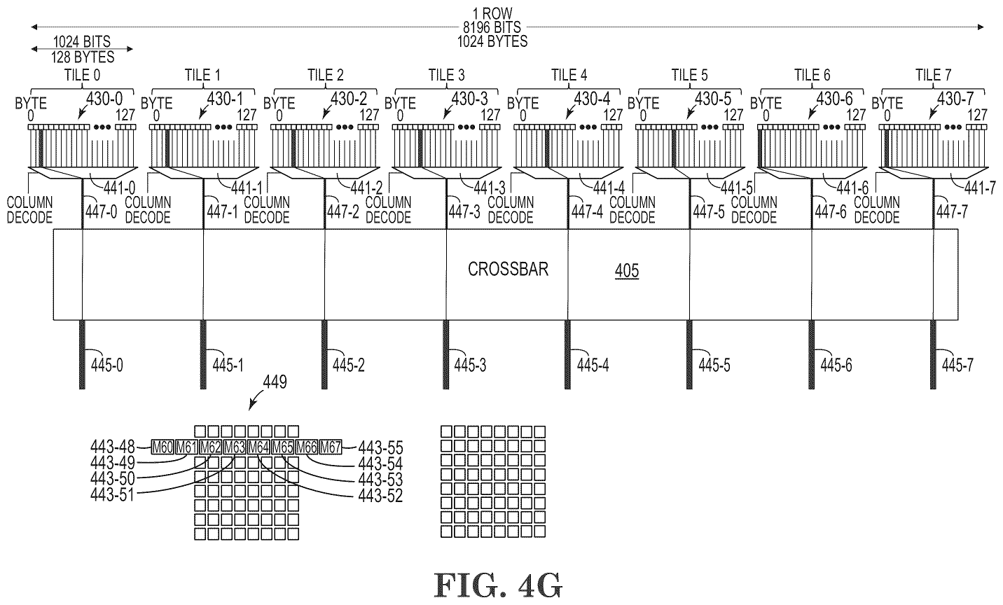

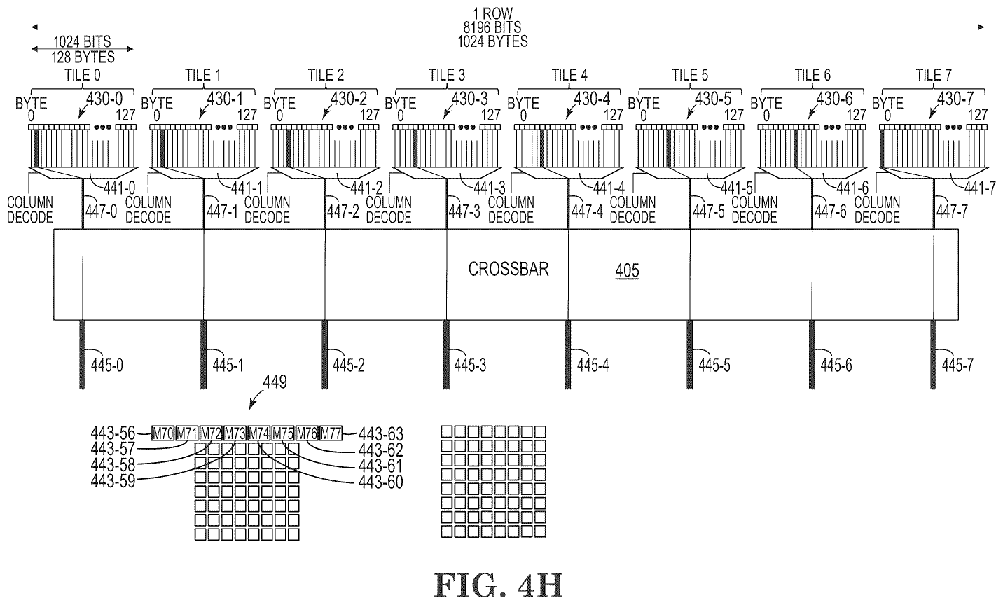

FIGS. 3A to 3H illustrate a conceptual example of sensing data values of a column of a matrix from an array of a memory device and/or providing data values of the column of the matric to the array in accordance with an embodiment of the present disclosure. FIGS. 4A to 4H illustrate a conceptual example of sensing data values of a row of a matrix from an array of memory cells of a memory device in accordance with an embodiment of the present disclosure.

FIGS. 3A to 3H include a memory array having sub-arrays 330-0, 330-1, 330-2, 330-3, 330-4, 330-5, 330-6, 330-7. The sub-arrays 330-0, 330-1, 330-2, 330-3, 330-4, 330-5, 330-6, 330-7 can be referred to as sub-arrays 330. The FIGS. 3A to 3H also include multiplexors (MUXs) 341-0, 341-1, 341-2, 341-3, 341-4, 341-5, 341-6, 341-7, referred to as MUXs 341. The FIGS. 3A to 3H further include lines 347-0, 347-1, 347-2, 347-3, 347-4, 347-5, 347-6, 347-7, referred to as lines (e.g., input lines) 347, and lines 345-0, 345-1, 345-2, 345-3, 345-4, 345-5, 345-6, 345-7, referred to as lines (e.g., output lines) 345. The FIGS. 3A to 3H include a crossbar 305 and a matrix 349. The matrix 349 includes data values 343-0, 343-1, . . . 343-63, referred to as data values 343 (e.g., M00, . . . , M77).

FIG. 3A is a block diagram of a crossbar 305 in a first configuration in accordance with a number of embodiments of the present disclosure. FIG. 3A shows data values 343-0, 343-1, 343-2, 343-3, 343-4, 343-5, 343-6, 343-7 of a first column of a matrix. The example of FIG. 3A shows the data values of the first column being provided (e.g., stored) to the sub-arrays 330 or being sensed (e.g., read) from the sub-arrays 330.

The crossbar 305 can receive an indication that the data values received by the crossbar 305 are arranged in a first column of the matrix 349. The crossbar 305 can receive the data values from the lines 345 if the data values are being stored to the sub-arrays 330. The crossbar 305 can receive the data values from the lines 347 if the data values are being sensed from the sub-arrays 330 and/or are being provided to the lines 345.

The crossbar 305 can have a number of configurations. As used herein, a configuration of the crossbar 305 describes how the crossbar 305 couples the lines 347 to the lines 345. For instance, the crossbar 305 can have a first configuration to read and/or store the data values 343-0, 343-1, 343-2, 343-3, 343-4, 343-5, 343-6, 343-7 of a first column of a matrix.

In a first configuration that stores and/or reads a first column of a matrix, the crossbar 305 can couple the line 347-0 to the line 345-0, the line 347-1 to the line 345-1, the line 347-2 to the line 345-2, the line 347-3 to the line 345-3, the line 347-4 to the line 345-4, the line 347-5 to the line 345-5, the line 347-6 to the line 345-6, and the line 347-7 to the line 345-7. Each of the lines 345 and the lines 347 can be assigned an address. In a first configuration the lines 345 are coupled to the lines 347 having a same address. For instance, the line 345-0 having a first address is coupled to the line 347-0 also having the first address. Coupling lines that have a same address can be described as coupling the lines “in line”.

The lines 345 can be directly coupled to the lines 347. For example, the lines 345-0, 347-0 can be used to store or read the data values 343-0. The lines 345-1, 347-1 can be used to store or read the data values 343-1. The lines 345-2, 347-2 can be used to store or read the data values 343-2. The lines 345-3, 347-3 can be used to store or read the data values 343-3. The lines 345-4, 347-4 can be used to store or read the data values 343-4. The lines 345-5, 347-5 can be used to store or read the data values 343-5. The lines 345-6, 347-6 can be used to store or read the data values 343-6. The lines 345-7, 347-7 can be used to store or read the data values 343-7. Directly coupling the lines 345 to the lines 347 can also be referred to as coupling the lines “in line”.

Because the lines 345 are directly coupled to the lines 347, a first data value 343-0 can be stored in the sub-array 330-0 in memory cells having a first address (e.g., having least significant bits of an address indicating a first address “000”-bits). The rest of the data values 343 can be stored or read from memory cells of the sub-arrays 330 having a first address.

The MUXs 341 can represent sense amplifiers and the MUXs 341.

The MUXs 341 can be implemented in the sensing circuitry of the memory device. In various examples, the MUXs 341 can be implemented externally to the sense circuitry. For example, the MUXs 341 can be implemented as part of the crossbar 305 (e.g., not shown).

In the example of FIG. 3A each of the sub-arrays 330 can include 1024 bits per row of memory cells of the sub-arrays 330. The 1024 bits can be divided into 128 bytes. The sense amplifiers (e.g., not shown) can be used to provide eights bites of data to the MUXs 341. Each of the data values 343 can be eight bits of data. The MUXs 341 can select a byte of data (e.g., a data value 343) and provide the byte of data to the lines 347.

FIG. 3B is a block diagram of a crossbar 305 in a second configuration in accordance with a number of embodiments of the present disclosure. FIG. 3B shows data values 343-8, 343-9, 343-10, 343-11, 343-12, 343-13, 343-14, 343-15 of a second column of a matrix 349. The example of FIG. 3B shows the data values of the second column being programmed (e.g., stored) to the sub-arrays 330 or being sensed (e.g., read) from the sub-arrays 330.

The crossbar 305 can receive an indication that the data values received by the crossbar 305 are arranged in a second column of the matrix 349. The crossbar 305 can have a second configuration to read and/or store the data values 343-8, 343-9, 343-10, 343-11, 343-12, 343-13, 343-14, 343-15 of a second column of a matrix 349. The second configuration can be utilized to store the second column of the matrix 349.

In the second configuration that is used to store and/or read the second column of the matrix 349, the crossbar 305 can couple the line 347-0 to the line 345-7, the line 347-1 to the line 345-0, the line 347-2 to the line 345-1, the line 347-3 to the line 345-2, the line 347-4 to the line 345-3, the line 347-5 to the line 345-4, the line 347-6 to the line 345-5, and the line 347-7 to the line 345-6. Each of the lines 345 and the lines 347 can be assigned an address. In the second configuration the lines 345 are coupled to the lines 347 having an address offset by one. For instance, the line 345-0 having a first address is coupled to the line 347-1 having a second address.

The lines 345 can be coupled to the lines 347 being offset by one line. For example, the lines 345-0, 347-1 can be used to store or read the data values 343-8. The lines 345-1, 347-2 can be used to store or read the data values 343-9. The lines 345-2, 347-3 can be used to store or read the data values 343-10. The lines 345-3, 347-4 can be used to store or read the data values 343-11. The lines 345-4, 347-5 can be used to store or read the data values 343-12. The lines 345-5, 347-6 can be used to store or read the data values 343-13. The lines 345-6, 347-7 can be used to store or read the data values 343-14. The lines 345-7, 347-0 can be used to store or read the data values 343-15.

Because the lines 345 are coupled to the lines 347 such that they are offset by one line, a second data value 343-9 of the second column can be stored in the sub-array 330-0 in memory cells having a second address (e.g., having least significant bits of an address indicating a second address “001”-bits). The rest of the data values 343 can be stored or read from memory cells of the sub-arrays 330 having the second address.

The matrix 349 is shown to represent the storage of the data values 343 in the sub-arrays 330. For example, although the data values 343-0, 343-8 are part of a same row of the logical matrix, they are shown in the matrix 349 as being diagonal from each other. For example, the data value 343-0 is shown as being in a first column and a first row of the matrix 349. The data value 343-9 is being shown as being in the second column and the second row of the matrix 349. The matrix 349 represents the offset nature of the storage of the data values 343 in the sub-arrays 330. The columns of the matrix 349 are output from the crossbar 305 and provided to the lines 345 such that the data values of a row of the matrix 349 are provided via the same line from the lines 345. For instance, the data values 343-0, 343-8 are provided to the sub-arrays 330 via the line 345-0 if the data values 343-0 are being stored in the sub-arrays 330 or are provided from the sub-arrays 330 and to the line 345-0 if the data values 343-0, 343-8 are being read from the sub-arrays 330.

FIG. 3C is a block diagram of a crossbar 305 in a third configuration in accordance with a number of embodiments of the present disclosure. FIG. 3C shows data values 343-16, 343-17, 343-18, 343-19, 343-20, 343-21, 343-22, 343-23, of a third column of the matrix 349. The example of FIG. 3C shows the data values of the third column being stored to the sub-arrays 330 or being sensed (e.g., read) from the sub-arrays 330.

The crossbar 305 can receive an indication that the data values received by the crossbar 305 are arranged in a third column of the matrix 349. The crossbar 305 can have a third configuration to read and/or store the data values 343-16, 343-17, 343-18, 343-19, 343-20, 343-21, 343-22, 343-23, of the third column of the matrix 349. The third configuration can be utilized to store the third column of the matrix 349.

In the third configuration that is used to store and/or read the third column of the matrix 349, the crossbar 305 can couple the line 347-0 to the line 345-6, the line 347-1 to the line 345-7, the line 347-2 to the line 345-0, the line 347-3 to the line 345-1, the line 347-4 to the line 345-2, the line 347-5 to the line 345-3, the line 347-6 to the line 345-4, and the line 347-7 to the line 345-5. Each of the lines 345 and the lines 347 can be assigned an address. In the third configuration the lines 345 are coupled to the lines 347 having an address offset by two. For instance, the line 345-0 having a first address is coupled to the line 347-2 having a third address.

The lines 345 can be coupled to the lines 347 being offset by two lines. For example, the lines 345-0, 347-2 can be used to store or read the data values 343-16. The lines 345-1, 347-3 can be used to store or read the data values 343-17. The lines 345-2, 347-4 can be used to store or read the data values 343-18. The lines 345-3, 347-5 can be used to store or read the data values 343-19. The lines 345-4, 347-6 can be used to store or read the data values 343-20. The lines 345-5, 347-7 can be used to store or read the data values 343-21. The lines 345-6, 347-0 can be used to store or read the data values 343-22. The lines 345-7, 347-1 can be used to store or read the data values 343-23.

Because the lines 345 are coupled to the lines 347 such that they are offset by two lines, a third data value 343-18 of the third column can be stored in the sub-array 330-0 in memory cells having a third address (e.g., having least significant bits of an address indicating a third address “010”-bits). The rest of the data values 343 can be stored or read from memory cells of the sub-arrays 330 having the third address.

FIG. 3D is a block diagram of a crossbar 305 in a fourth configuration in accordance with a number of embodiments of the present disclosure. FIG. 3D shows data values 343-24, 343-25, 343-26, 343-27, 343-28, 343-29, 343-30, 343-31, of a fourth column of the matrix 349. The example of FIG. 3D shows the data values of the fourth column being stored to the sub-arrays 330 or being sensed (e.g., read) from the sub-arrays 330.

The crossbar 305 can receive an indication that the data values received by the crossbar 305 are arranged in a fourth column of the matrix 349. The crossbar 305 can have a fourth configuration to read and/or store the data values 343-24, 343-25, 343-26, 343-27, 343-28, 343-29, 343-30, 343-31, of the fourth column of the matrix 349. The fourth configuration can be utilized to store the fourth column of the matrix 349.

In the fourth configuration that is used to store and/or read the fourth column of the matrix 349, the crossbar 305 can couple the line 347-0 to the line 345-5, the line 347-1 to the line 345-6, the line 347-2 to the line 345-7, the line 347-3 to the line 345-0, the line 347-4 to the line 345-1, the line 347-5 to the line 345-2, the line 347-6 to the line 345-3, and the line 347-7 to the line 345-4. Each of the lines 345 and the lines 347 can be assigned an address. In the fourth configuration the lines 345 are coupled to the lines 347 having an address offset by three. For instance, the line 345-0 having a first address is coupled to the line 347-3 having a fourth address.

The lines 345 can be coupled to the lines 347 being offset by three lines. For example, the lines 345-0, 347-3 can be used to store or read the data values 343-24. The lines 345-1, 347-4 can be used to store or read the data values 343-25. The lines 345-2, 347-5 can be used to store or read the data values 343-26. The lines 345-3, 347-6 can be used to store or read the data values 343-27. The lines 345-4, 347-7 can be used to store or read the data values 343-28. The lines 345-5, 347-0 can be used to store or read the data values 343-29. The lines 345-6, 347-1 can be used to store or read the data values 343-30. The lines 345-7, 347-2 can be used to store or read the data values 343-31.

Because the lines 345 are coupled to the lines 347 such that they are offset by three lines, a fourth data value 343-27 of the fourth column can be stored in the sub-array 330-0 in memory cells having a fourth address (e.g., having least significant bits of an address indicating a fourth address “011”-bits). The rest of the data values 343 can be stored or read from memory cells of the sub-arrays 330 having the fourth address.

FIG. 3E is a block diagram of a crossbar 305 in a fifth configuration in accordance with a number of embodiments of the present disclosure. FIG. 3E shows data values 343-32, 343-33, 343-34, 343-35, 343-36, 343-37, 343-38, 343-39, of a fifth column of the matrix 349. The example of FIG. 3E shows the data values of the fifth column being stored to the sub-arrays 330 or being sensed (e.g., read) from the sub-arrays 330.

The crossbar 305 can receive an indication that the data values received by the crossbar 305 are arranged in a fifth column of the matrix 349. The crossbar 305 can have a fifth configuration to read and/or store the data values 343-32, 343-33, 343-34, 343-35, 343-36, 343-37, 343-38, 343-39, of the fifth column of the matrix 349. The fifth configuration can be utilized to store the fifth column of the matrix 349.

In the fifth configuration that is used to store and/or read the fifth column of the matrix 349, the crossbar 305 can couple the line 347-0 to the line 345-4, the line 347-1 to the line 345-5, the line 347-2 to the line 345-6, the line 347-3 to the line 345-7, the line 347-4 to the line 345-0, the line 347-5 to the line 345-1, the line 347-6 to the line 345-2, and the line 347-7 to the line 345-3. Each of the lines 345 and the lines 347 can be assigned an address. In the fifth configuration the lines 345 are coupled to the lines 347 having an address offset by four lines. For instance, the line 345-0 having a first address is coupled to the line 347-4 having a fifth address.

The lines 345 can be coupled to the lines 347 being offset by four lines. For example, the lines 345-0, 347-4 can be used to store or read the data values 343-32. The lines 345-1, 347-5 can be used to store or read the data values 343-33. The lines 345-2, 347-6 can be used to store or read the data values 343-34. The lines 345-3, 347-7 can be used to store or read the data values 343-35. The lines 345-4, 347-0 can be used to store or read the data values 343-36. The lines 345-5, 347-1 can be used to store or read the data values 343-37. The lines 345-6, 347-2 can be used to store or read the data values 343-38. The lines 345-7, 347-3 can be used to store or read the data values 343-39.

Because the lines 345 are coupled to the lines 347 such that they are offset by four lines, a fifth data value 343-32 of the fifth column can be stored in the sub-array 330-0 in memory cells having a fifth address (e.g., having least significant bits of an address indicating a fifth address “011”-bits). The rest of the data values 343 can be stored or read from memory cells of the sub-arrays 330 having the fifth address.

FIG. 3F is a block diagram of a crossbar 305 in a sixth configuration in accordance with a number of embodiments of the present disclosure. FIG. 3F shows data values 343-40, 343-41, 343-42, 343-43, 343-44, 343-45, 343-46, 343-47, of a sixth column of the matrix 349. The example of FIG. 3F shows the data values of the sixth column being stored to the sub-arrays 330 or being sensed (e.g., read) from the sub-arrays 330.

The crossbar 305 can receive an indication that the data values received by the crossbar 305 are arranged in a sixth column of the matrix 349. The crossbar 305 can have a sixth configuration to read and/or store the data values 343-40, 343-41, 343-42, 343-43, 343-44, 343-45, 343-46, 343-47, of the sixth column of the matrix 349. The sixth configuration can be utilized to store the sixth column of the matrix 349.

In the sixth configuration that is used to store and/or read the sixth column of the matrix 349, the crossbar 305 can couple the line 347-0 to the line 345-3, the line 347-1 to the line 345-4, the line 347-2 to the line 345-5, the line 347-3 to the line 345-6, the line 347-4 to the line 345-7, the line 347-5 to the line 345-0, the line 347-6 to the line 345-1, and the line 347-7 to the line 345-2. Each of the lines 345 and the lines 347 can be assigned an address. In the sixth configuration the lines 345 are coupled to the lines 347 having an address offset by five lines. For instance, the line 345-0 having a first address is coupled to the line 347-5 having a sixth address.

The lines 345 can be coupled to the lines 347 being offset by five lines. For example, the lines 345-0, 347-5 can be used to store or read the data values 343-40. The lines 345-1, 347-6 can be used to store or read the data values 343-41. The lines 345-2, 347-7 can be used to store or read the data values 343-42. The lines 345-3, 347-0 can be used to store or read the data values 343-43. The lines 345-4, 347-1 can be used to store or read the data values 343-33. The lines 345-5, 347-2 can be used to store or read the data values 343-45. The lines 345-6, 347-3 can be used to store or read the data value 343-46. The lines 345-7, 347-4 can be used to store or read the data value 343-47.

Because the lines 345 are coupled to the lines 347 such that they are offset by five lines, a sixth data value 343-40 of the sixth column can be stored in the sub-array 330-0 in memory cells having a sixth address (e.g., having least significant bits of an address indicating a sixth address “100”-bits). The rest of the data values 343 can be stored or read from memory cells of the sub-arrays 330 having the sixth address.

FIG. 3G is a block diagram of a crossbar 305 in a seventh configuration in accordance with a number of embodiments of the present disclosure. FIG. 3G shows data values 343-48, 343-49, 343-50, 343-51, 343-52, 343-53, 343-54, 343-55, of a seventh column of the matrix 349. The example of FIG. 3G shows the data values of the seventh column being stored to the sub-arrays 330 or being sensed (e.g., read) from the sub-arrays 330.

The crossbar 305 can receive an indication that the data values received by the crossbar 305 are arranged in a seventh column of the matrix 349. The crossbar 305 can have a seventh configuration to read and/or store the data values 343-48, 343-49, 343-50, 343-51, 343-52, 343-53, 343-54, 343-55, of the seventh column of the matrix 349. The seventh configuration can be utilized to store the seventh column of the matrix 349.

In the seventh configuration that is used to store and/or read the seventh column of the matrix 349, the crossbar 305 can couple the line 347-0 to the line 345-2, the line 347-1 to the line 345-3, the line 347-2 to the line 345-4, the line 347-3 to the line 345-5, the line 347-4 to the line 345-6, the line 347-5 to the line 345-7, the line 347-6 to the line 345-0, and the line 347-7 to the line 345-1. Each of the lines 345 and the lines 347 can be assigned an address. In the seventh configuration the lines 345 are coupled to the lines 347 having an address offset by seven lines. For instance, the line 345-0 having a first address is coupled to the line 347-6 having a seventh address.

The lines 345 can be coupled to the lines 347 being offset by six lines. For example, the lines 345-0, 347-6 can be used to store or read the data values 343-48. The lines 345-1, 347-7 can be used to store or read the data values 343-49. The lines 345-2, 347-0 can be used to store or read the data values 343-50. The lines 345-3, 347-1 can be used to store or read the data values 343-51. The lines 345-4, 347-2 can be used to store or read the data values 343-52. The lines 345-5, 347-3 can be used to store or read the data values 343-53. The lines 345-6, 347-4 can be used to store or read the data value 343-54. The lines 345-7, 347-5 can be used to store or read the data value 343-55.

Because the lines 345 are coupled to the lines 347 such that they are offset by six lines, a seventh data value 343-48 of the seventh column can be stored in the sub-array 330-0 in memory cells having a seventh address (e.g., having least significant bits of an address indicating a seventh address “101”-bits). The rest of the data values 343 can be stored or read from memory cells of the sub-arrays 330 having the seventh address.

FIG. 3H is a block diagram of a crossbar 305 in an eighth configuration in accordance with a number of embodiments of the present disclosure. FIG. 3H shows data values 343-56, 343-57, 343-58, 343-59, 343-60, 343-61, 343-62, 343-63, of an eighth column of the matrix 349. The example of FIG. 3H shows the data values of the eighth column being stored to the sub-arrays 330 or being sensed (e.g., read) from the sub-arrays 330.

The crossbar 305 can receive an indication that the data values received by the crossbar 305 are arranged in an eighth column of the matrix 349. The crossbar 305 can have an eighth configuration to read and/or store the data values 343-56, 343-57, 343-58, 343-59, 343-60, 343-61, 343-62, 343-63, of the eighth column of the matrix 349. The eighth configuration can be utilized to store the eighth column of the matrix 349.

In the eighth configuration that is used to store and/or read the eighth column of the matrix 349, the crossbar 305 can couple the line 347-0 to the line 345-1, the line 347-1 to the line 345-2, the line 347-2 to the line 345-3, the line 347-3 to the line 345-4, the line 347-4 to the line 345-5, the line 347-5 to the line 345-6, the line 347-6 to the line 345-7, and the line 347-7 to the line 345-0. Each of the lines 345 and the lines 347 can be assigned an address. In the eighth configuration the lines 345 are coupled to the lines 347 having an address offset by eight lines. For instance, the line 345-0 having a first address is coupled to the line 347-7 having an eighth address.

The lines 345 can be coupled to the lines 347 being offset by seven lines. For example, the lines 345-0, 347-7 can be used to store or read the data values 343-56. The lines 345-1, 347-0 can be used to store or read the data values 343-57. The lines 345-2, 347-1 can be used to store or read the data values 343-58. The lines 345-3, 347-2 can be used to store or read the data values 343-59. The lines 345-4, 347-3 can be used to store or read the data values 343-60. The lines 345-5, 347-4 can be used to store or read the data values 343-61. The lines 345-6, 347-5 can be used to store or read the data value 343-62. The lines 345-7, 347-6 can be used to store or read the data value 343-63.

Because the lines 345 are coupled to the lines 347 such that they are offset by seven lines, a seventh data value 343-56 of the eighth column can be stored in the sub-array 330-0 in memory cells having an eighth address (e.g., having least significant bits of an address indicating an eighth address “110”-bits). The rest of the data values 343 can be stored or read from memory cells of the sub-arrays 330 having the eighth address.

FIGS. 4A to 4H include a memory having sub-arrays 430-0, 430-1, 430-2, 430-3, 430-4, 430-5, 430-6, 430-7. The sub-arrays 430-0, 430-1, 430-2, 430-3, 430-4, 430-5, 430-6, 430-7 can be referred to as sub-arrays 430. The FIGS. 4A to 4H also include MUXs 441-0, 441-1, 441-2, 441-3, 441-4, 441-5, 441-6, 441-7, referred to as MUXs 441. The FIGS. 4A to 4H further include lines 447-0, 447-1, 447-2, 447-3, 447-4, 447-5, 447-6, 447-7, referred to as lines (e.g., input lines) 447, and lines 445-0, 445-1, 445-2, 445-3, 445-4, 445-5, 445-6, 445-7, referred to as lines (e.g., output lines) 445. The FIGS. 4A to 4H include a crossbar 405 and a matrix 449. The matrix 449 includes data values 443-0, 443-1, . . . , 443-63, referred to as data values 443 (e.g., M00, . . . , M77).

FIG. 4A is a block diagram of a crossbar 405 receiving data values having different addresses in accordance with a number of embodiments of the present disclosure. FIGS. 4A to 4H provide an example of reading data values of a row of a matrix. FIG. 4A shows the data values 443-0, 443-1, 443-2, 443-3, 443-4, 443-5, 443-6, 443-7 (e.g., M00, M01, M02, M03, M04, M05, M06, M07) of a first row of a matrix. The first row of data values can have previously been stored in the sub-arrays 430. For example, the matrix 449 can previously have been stored in the sub-arrays 430 using the examples provided in FIGS. 4A to 4H.

The crossbar 405 can receive an indication that the data values received by the crossbar 405 are arranged in a first row of the matrix 449. The crossbar 405 can receive the data values from the lines 447 if the data values are being read from the sub-arrays 430 and/or are being provided to the lines 445.

Responsive to the crossbar 405 receiving the indication that the data values are arranged in a row of the matrix 449, the crossbar 405 can use the first configuration to provide each of the rows of the matrix 449 to the lines 445. The coupling of the lines 445 to the lines 447 does not change based on the particular row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1.

The data values selected by the MUXs 441 and provided to the lines 447 can also be based on a particular row of the matrix 449 being read. For example, the MUXs 441 can receive an indication that a first row, a second row, a third row etc. is being read. The indication that a row is being read and the particular row being read can be provided from the registers 104 of FIG. 1.

The data values selected by the MUXs 441 and provided to the lines 447 can also be based on an address received by the MUXs 441. In various instances, the MUXs 441 can receive an address instead of an indication that a row is being read. In other examples, the MUXs 441 can generate a plurality of addresses from the indication that a row is being read.

The column decoder 152 of FIG. 1 can provide one or more addresses to the MUXs 441. The MUXs 441 can utilize the indication that a row is being read, the particular row, and/or the one or more addresses to select data values and provide the data values to the lines 445. For example, the column decoder of the memory device can receive an indication that a row is being read and/or an indication that a particular row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a first row of the matrix 439 being read can cause the MUXs 441 to be configured using a first configuration. For example, given that a first row of the matrix 449 is being read, the column decoder can provide a first address (e.g., “000”) to the MUX 441-0, a second addresses (e.g., “001”) to the MUX 441-1, a third address (e.g., “010”) to the MUX 441-2, a fourth addresses (e.g., “011”) to the MUX 441-3, a fifth address (e.g., “100”) to the MUX 441-4, a sixth addresses (e.g., “101”) to the MUX 441-5, a seventh address (e.g., “110”) to the MUX 441-6, and an eighth addresses (e.g., “111”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a first row of the matrix 449 to the lines 445.

FIG. 4B is a block diagram of a crossbar 405 receiving data values having different addresses in accordance with a number of embodiments of the present disclosure. FIG. 4B shows the data values 443-8, 443-9, 443-10, 443-11, 443-12, 443-13, 443-14, 443-15 (e.g., M10, M11, M12, M13, M14, M15, M16, M17) of a second row of the matrix 449.

The crossbar 405 can receive an indication that the data values received by the crossbar 405 are arranged in a second row of the matrix 449. Responsive to the crossbar 405 receiving the indication that the data values are arranged in a row of the matrix 449, the crossbar 405 can use a second configuration to provide the second row of the matrix 449 to the lines 445. The coupling of the lines 445 to the lines 447 does not change based on the second row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the second row and provide the data values to the lines 445. For example, the column decoder of the memory device can receive an indication that a row is being read and/or an indication that a second row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a second row of the matrix 439 being read can cause the MUXs 441 to be configured using a second configuration. For example, given that a second row of the matrix 449 is being read, the column decoder can provide an eighth address (e.g., “111”) to the MUX 441-0, a first addresses (e.g., “000”) to the MUX 441-1, a second address (e.g., “001”) to the MUX 441-2, a third addresses (e.g., “010”) to the MUX 441-3, a fourth address (e.g., “011”) to the MUX 441-4, a fifth addresses (e.g., “100”) to the MUX 441-5, a sixth address (e.g., “101”) to the MUX 441-6, and a seventh addresses (e.g., “110”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a second row of the matrix 449 to the lines 445.

FIG. 4C is a block diagram of a crossbar 405 receiving data values having different addresses in accordance with a number of embodiments of the present disclosure. FIG. 4C shows the data values 443-16, 443-17, 443-18, 443-19, 443-20, 443-21, 443-22, 443-23 (e.g., M20, M21, M22, M23, M24, M25, M26, M27) of a third row of the matrix 449.

The crossbar 405 can receive an indication that the data values received by the crossbar 405 are arranged in a third row of the matrix 449. Responsive to the crossbar 405 receiving the indication that the data values are arranged in a row of the matrix 449, the crossbar 405 can use a third configuration to provide the third row of the matrix 449 to the lines 445. The coupling of the lines 445 to the lines 447 does not change based on the third row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the third row and provide the data values to the lines 445. For example, the column decoder of the memory device can receive an indication that a row is being read and/or an indication that a third row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a third row of the matrix 439 being read can cause the MUXs 441 to be configured using a third configuration. For example, given that a third row of the matrix 449 is being read, the column decoder can provide a seventh address (e.g., “110”) to the MUX 441-0, an eighth addresses (e.g., “111”) to the MUX 441-1, a first address (e.g., “000”) to the MUX 441-2, a second addresses (e.g., “001”) to the MUX 441-3, a third address (e.g., “010”) to the MUX 441-4, a fourth addresses (e.g., “011”) to the MUX 441-5, a fifth address (e.g., “100”) to the MUX 441-6, and a sixth addresses (e.g., “101”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a third row of the matrix 449 to the lines 445.

FIG. 4D is a block diagram of a crossbar 405 receiving data values having different addresses in accordance with a number of embodiments of the present disclosure. FIG. 4D shows the data values 443-24, 443-25, 443-26, 443-27, 443-28, 443-29, 443-30, 443-31 (e.g., M30, M31, M32, M33, M34, M35, M36, M37) of a fourth row of the matrix 449.

The crossbar 405 can receive an indication that the data values received by the crossbar 405 are arranged in a fourth row of the matrix 449. Responsive to the crossbar 405 receiving the indication that the data values are arranged in a row of the matrix 449, the crossbar 405 can use a fourth configuration to provide the fourth row of the matrix 449 to the lines 445. The coupling of the lines 445 to the lines 447 does not change based on the fourth row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the fourth row and provide the data values to the lines 445. For example, the column decoder of the memory device can receive an indication that a row is being read and/or an indication that a fourth row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a fourth row of the matrix 439 being read can cause the MUXs 441 to be configured using a fourth configuration. For example, given that a fourth row of the matrix 449 is being read, the column decoder can provide a sixth address (e.g., “101”) to the MUX 441-0, a seventh addresses (e.g., “110”) to the MUX 441-1, an eighth address (e.g., “111”) to the MUX 441-2, a first addresses (e.g., “000”) to the MUX 441-3, a second address (e.g., “001”) to the MUX 441-4, a third addresses (e.g., “010”) to the MUX 441-5, a fourth address (e.g., “011”) to the MUX 441-6, and a fifth addresses (e.g., “100”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a fourth row of the matrix 449 to the lines 445.

FIG. 4E is a block diagram of a crossbar 405 receiving data values having different addresses in accordance with a number of embodiments of the present disclosure. FIG. 4E shows the data values 443-32, 443-33, 443-34, 443-35, 443-36, 443-37, 443-38, 443-39 (e.g., M40, M41, M42, M43, M44, M45, M46, M47) of a fifth row of the matrix 449.

The crossbar 405 can receive an indication that the data values received by the crossbar 405 are arranged in a fifth row of the matrix 449. Responsive to the crossbar 405 receiving the indication that the data values are arranged in a row of the matrix 449, the crossbar 405 can use a fifth configuration to provide the fifth row of the matrix 449 to the lines 445. The coupling of the lines 445 to the lines 447 does not change based on the fifth row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the fifth row and provide the data values to the lines 445. For example, the column decoder of the memory device can receive an indication that a row is being read and/or an indication that a fifth row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a fifth row of the matrix 439 being read can cause the MUXs 441 to be configured using a fifth configuration. For example, given that a fifth row of the matrix 449 is being read, the column decoder can provide a fifth address (e.g., “100”) to the MUX 441-0, a sixth addresses (e.g., “101”) to the MUX 441-1, a seventh address (e.g., “110”) to the MUX 441-2, an eighth addresses (e.g., “111”) to the MUX 441-3, a first address (e.g., “000”) to the MUX 441-4, a second addresses (e.g., “001”) to the MUX 441-5, a third address (e.g., “010”) to the MUX 441-6, and a fourth addresses (e.g., “011”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a fifth row of the matrix 449 to the lines 445.

FIG. 4F is a block diagram of a crossbar 405 receiving data values having different addresses in accordance with a number of embodiments of the present disclosure. FIG. 4F shows the data values 443-40, 443-41, 443-42, 443-43, 443-44, 443-45, 443-46, 443-47 (e.g., M50, M51, M52, M53, M54, M55, M56, M57) of a sixth row of the matrix 449.

The crossbar 405 can receive an indication that the data values received by the crossbar 405 are arranged in a sixth row of the matrix 449. Responsive to the crossbar 405 receiving the indication that the data values are arranged in a row of the matrix 449, the crossbar 405 can use a sixth configuration to provide the sixth row of the matrix 449 to the lines 445. The coupling of the lines 445 to the lines 447 does not change based on the sixth row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the sixth row and provide the data values to the lines 445. For example, the column decoder of the memory device can receive an indication that a row is being read and/or an indication that a sixth row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a sixth row of the matrix 439 being read can cause the MUXs 441 to be configured using a sixth configuration. For example, given that a sixth row of the matrix 449 is being read, the column decoder can provide a fourth address (e.g., “011”) to the MUX 441-0, a fifth addresses (e.g., “100”) to the MUX 441-1, a sixth address (e.g., “101”) to the MUX 441-2, a seventh addresses (e.g., “110”) to the MUX 441-3, an eighth address (e.g., “111”) to the MUX 441-4, a first addresses (e.g., “000”) to the MUX 441-5, a second address (e.g., “001”) to the MUX 441-6, and a third addresses (e.g., “010”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a sixth row of the matrix 449 to the lines 445.

FIG. 4G is a block diagram of a crossbar 405 receiving data values having different addresses in accordance with a number of embodiments of the present disclosure. FIG. 4G shows the data values 443-48, 443-49, 443-50, 443-51, 443-52, 443-53, 443-54, 443-55 (e.g., M60, M61, M62, M63, M64, M65, M66, M67) of a seventh row of the matrix 449.

The crossbar 405 can receive an indication that the data values received by the crossbar 405 are arranged in a seventh row of the matrix 449. Responsive to the crossbar 405 receiving the indication that the data values are arranged in a row of the matrix 449, the crossbar 405 can use a seventh configuration to provide the seventh row of the matrix 449 to the lines 445. The coupling of the lines 445 to the lines 447 does not change based on the seventh row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the seventh row and provide the data values to the lines 445. For example, the column decoder of the memory device can receive an indication that a row is being read and/or an indication that a seventh row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to a seventh row of the matrix 439 being read can cause the MUXs 441 to be configured using a seventh configuration. For example, given that a seventh row of the matrix 449 is being read, the column decoder can provide a third address (e.g., “010”) to the MUX 441-0, a fourth addresses (e.g., “011”) to the MUX 441-1, a fifth address (e.g., “100”) to the MUX 441-2, a sixth addresses (e.g., “101”) to the MUX 441-3, a seventh address (e.g., “110”) to the MUX 441-4, an eight addresses (e.g., “111”) to the MUX 441-5, a first address (e.g., “000”) to the MUX 441-6, and a second addresses (e.g., “001”) to the MUX 441-7.

The MUXs 441 can utilize the addresses received from the column decoder to select data values stored in memory cells having said addresses and provide the data values to the crossbar 405 via the lines 447. The crossbar 405 can provide the data values of a seventh row of the matrix 449 to the lines 445.

FIG. 4H is a block diagram of a crossbar 405 receiving data values having different addresses in accordance with a number of embodiments of the present disclosure. FIG. 4H shows the data values 443-56, 443-57, 443-58, 443-59, 443-60, 443-61, 443-62, 443-63 (e.g., M70, M71, M72, M73, M74, M75, M76, M77) of an eighth row of the matrix 449.

The crossbar 405 can receive an indication that the data values received by the crossbar 405 are arranged in an eighth row of the matrix 449. Responsive to the crossbar 405 receiving the indication that the data values are arranged in a row of the matrix 449, the crossbar 405 can use an eighth configuration to provide the eighth row of the matrix 449 to the lines 445. The coupling of the lines 445 to the lines 447 does not change based on the eighth row of the matrix 449 being provided to the lines 445.

The data values selected by the MUXs 441 and provided to the lines 447 can be based on whether a row or a column of the matrix 449 is being read. The indication that a row is being read can be provided from the registers 104 of FIG. 1 and/or from the registers 104 to the column decoder 152 of FIG. 1.

The column decoder 152 of FIG. 1 can provide one or more addresses to the MUXs 441. The MUXs 441 can utilize the indication that a row is being read, the particular row, and/or the one or more addresses to select data values of the eighth row and provide the data values to the lines 445. For example, the column decoder of the memory device can receive an indication that a row is being read and/or an indication that an eighth row of the array 449 is being read from the registers 104 of FIG. 1. Based on an indication, the column decoder can generate one or more addresses and can provide the addresses to the MUXs 441.

The addresses provided to the MUXs 441 can be staggered. The addresses provided by the column decoder to the MUXs 441 responsive to an eighth row of the matrix 439 being read can cause the MUXs 441 to be configured using an eighth configuration. For example, given that an eighth row of the matrix 449 is being read, the column decoder can provide a second address (e.g., “001”) to the MUX 441-0, a third addresses (e.g., “010”) to the MUX 441-1, a fourth address (e.g., “011”) to the MUX 441-2, a fifth addresses (e.g., “100”) to the MUX 441-3, a sixth address (e.g., “101”) to the MUX 441-4, a seventh addresses (e.g., “110”) to the MUX 441-5, an eighth address (e.g., “111”) to the MUX 441-6, and a first addresses (e.g., “000”) to the MUX 441-7.

The MUXs 441 can utilize the addresses received from the column decoder to select data values stored in memory cells having said addresses and provide the data values to the crossbar 405 via the lines 447. The crossbar 405 can provide the data values of an eighth row of the matrix 449 to the lines 445.

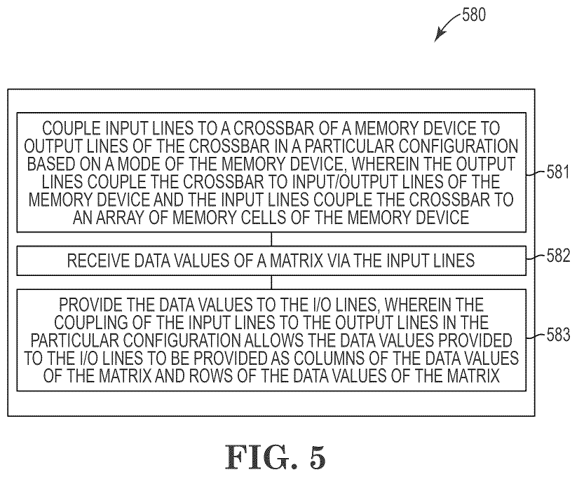

FIG. 5 illustrates an example flow diagram of a method 580 for accessing rows and columns of data values of a matrix stored in a memory device in accordance with a number of embodiments of the present disclosure. The method can be executed by a memory device of a computing system.

At 581, a crossbar (e.g., the crossbars 305, 405 of FIGS. 3A to 3H and 4A to 4H) of the memory device (e.g., the memory device 120 of FIG. 1) can couple input lines (e.g., input lines 347 of FIGS. 3A to 3H and input lines 447 of FIGS. 4A to 4H) to the crossbar to output lines (e.g., output lines 345 of FIGS. 3A to 3H and output lines 445 of FIGS. 4A to 4H) of the crossbar in a particular configuration based on a mode of the memory device, where the output lines couple the crossbar to I/O lines of the memory device and the input lines couple the crossbar to an array (e.g., array 130 of FIG. 1) of memory cells of the memory device. The mode can include a descriptor that describes whether the data values are a row or a column of the matrix.

The particular configuration can describe which of the input lines are coupled to which of the output lines. Each particular configuration can have a different coupling of input lines to output lines. In various instances, the output lines can be the I/O lines. For example, in FIGS. 3A to 3H and 4A to 4H, the lines 347, 447 are the input lines and the lines 345, 445 are the output lines and/or the I/O lines.

At 582, the crossbar can receive data values of a matrix (e.g., the matrix 349 and 449 of FIGS. 3A to 3H and 4A to 4H) via the input lines. The memory cells can be sensed by sensing circuitry (e.g., 150 of FIG. 1) of the memory device prior to providing the data values to the crossbar. A plurality of MUXs (e.g., MUXs 341 and 451 of FIGS. 3A to 3H and 4A to 4H) can determine which of the data values sensed are provided to the crossbar.

At 583, the crossbar can provide the data values to the I/O lines, wherein the coupling of the input lines to the output lines in the particular configuration allows the data values provided to the I/O lines to be provided as columns of the data values of the matrix and rows of the data values of the matrix. The coupling of input lines to the output lines includes coupling the input lines to the output lines in a first configuration based on the mode being a first mode, where each of the input lines is coupled to the output lines such that they are offset. The first mode can indicate that data values of a column of a matrix are being accessed (e.g., read).

Coupling the input lines to the output lines can include coupling the input lines to the output lines in a second configuration based on the mode being a second mode, wherein each of the input lines is coupled to the output lines in line. The second mode can indicate that data values of a row of a matrix are being accessed. The term “in line” indicates that the input lines are coupled to the output lines such that they are not offset.

In various instances, the addresses, from which the data values are retrieved, provided to the crossbar and/or the MUXs can be updated responsive to the mode being a second mode. The addresses can be updated, for example, by a column decoder 152 of FIG. 1. Updating the address from which the data values are retrieved includes updating an address for each MUX of the memory device that provides signals from the sense amplifiers of the memory device to the input lines. For example, Each MUX can be assigned and/or provided a different address from an adjacent MUX.

If the memory device is in a first mode, then the column decoder can refrain from updating an address from which the data values are retrieved from the array. The column decoder can provide a same address to each of the MUXs and/or the crossbar if the memory device is in a first mode.

In various examples, an apparatus can include an array of memory cells and a crossbar coupled to the array of memory cells. The crossbar can couple input lines to the cross bar to output lines from the cross bar in a particular configuration, wherein the output lines couple the cross bar to the array. The particular configuration can define which of the input lines are coupled to which of the output lines. The cross bar can receive data values of a matrix via the input lines to the crossbar.

The crossbar can provide the data values to the array via the output lines, wherein the particular configuration allows the data values provided to the array to be sensed as columns of the data values of the matrix and rows of the data values of the matrix. The particular configuration of the crossbar can determine an address of the array to which the data values are provided (e.g., stored). For example, without the crossbar the data values can be stored to memory cells having a first address. The crossbar having a particular configuration can store data values to memory cells having a second address based on the coupling of input lines to output lines.

The address in the array to which the data values are provided can be different than an address associated with the data values when received via the input lines. The crossbar can define the first address given that the crossbar can determine which data values are provided to which sub-arrays. For example, a first data value can be provided via a first input line. The crossbar can couple the first input line to a second output line thereby changing an address to which the first data value is saved in a third sub-array.

The particular configuration is one of a plurality of configurations for coupling the input lines to the output lines. The input lines can provide the data values to the crossbar consistent with a second address. For example, the crossbar can cause, based on the particular configuration, the data values to be provided on output lines based on a first address even though the input lines provided the data values to the crossbar consistent with a second address. Without the crossbar the input lines would provide a first data value to the sub-arrays to be saved in memory cells having a first address. With the crossbar the input lines can provide the first data value to the crossbar consistent with a first address. The crossbar can provide the first data value to the sub-arrays to be saved in memory cells having a second address.

The crossbar can utilize the plurality of configurations to sense the data values when the apparatus is in a first mode. Each of the plurality of configurations can be utilized to access a different column of the matrix.

The crossbar can couple the input lines to the crossbar to the output lines of the crossbar in the plurality of configurations. Each of the plurality of configurations can be used to access a different column from the plurality of columns. In various instances, a particular configuration can be used to access multiple columns. For example, if there are eight possible configurations but sixteen columns, then a first configuration can be used to access a first column and a ninth column while a second configuration is used to access a second column and a tenth column.

Each of the input lines can be couple to a different output line in each of the configurations, for the plurality of configurations. Each the plurality of configurations can correspond to a different column of the data values of the matrix.

In various examples, the apparatus can include an array of memory cells, a number of registers configured to store mode of the apparatus, and a plurality of MUXs that couple sense lines of the array to a first plurality of lines that couple the array to the crossbar, and a crossbar coupled to the number of registers and to the array of memory cells. The crossbar can access the mode from the number of registers. The crossbar can couple the first plurality of lines to a second plurality of lines in a first configuration based on the mode being a first mode and an address associated with the data values, wherein the second plurality of lines couples the crossbar to I/O lines of the apparatus. The crossbar can couple the first plurality of lines to the second plurality of lines in a second configuration based on the mode being a second mode and the address associated with the data values. The crossbar can receive data values of a matrix via the first plurality of lines. The crossbar can also provide the data values to the I/O lines via the second lines based on the mode being the first mode or the second mode, where the first configuration allows the data values to be sensed as columns of the matrix and the second configuration allows the data values to be sensed as rows of the matrix. The column decoder of the memory device can, responsive to the mode being the second mode, configure each of the MUXs differently.

The crossbar can cause the data values to be stored in the array such that each data value of the columns of the matrix is stored in a different sub-array of the array. The crossbar can cause the data values to be stored in the array utilizing a plurality of additional configurations for coupling the first plurality of lines to the second plurality of lines. The crossbar can couple the first plurality of lines to the second plurality of lines in the plurality of additional configurations.

The crossbar configured to couple the second plurality of lines to the first plurality of lines in a first configuration based on the mode being the first mode can further be configured to couple the second plurality of lines to the first plurality of lines in the plurality of additional configurations including the first configuration and the second configuration based on the mode being the second mode.

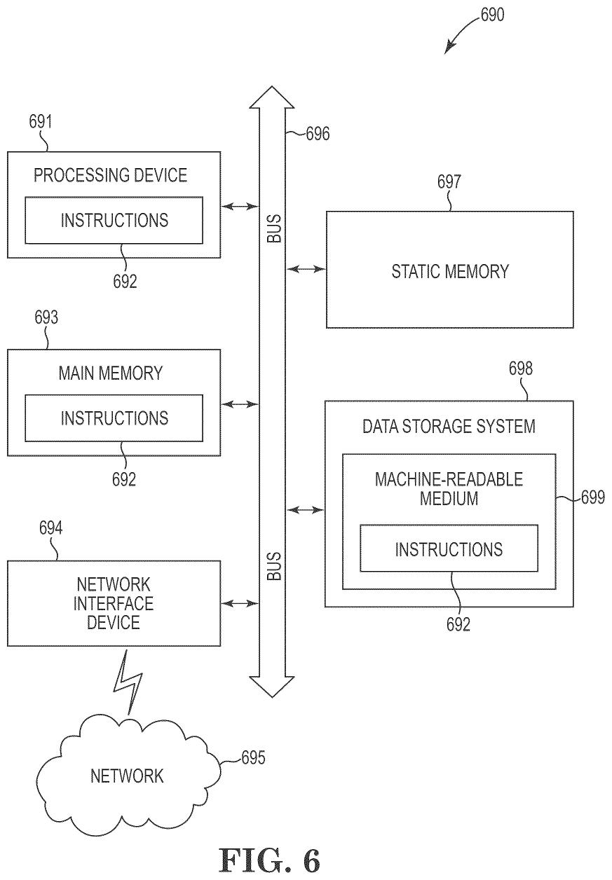

FIG. 6 illustrates an example machine of a computer system 690 within which a set of instructions, for causing the machine to perform any one or more of the methodologies discussed herein, can be executed. In some embodiments, the computer system 690 can correspond to a host system (e.g., the system 110 of FIG. 1) that includes, is coupled to, or utilizes a memory system (e.g., the memory device 120 of FIG. 1) or can be used to perform the operations of the crossbar and/or the MUXs (e.g., the crossbar 105 of FIG. 1 and/or the MUXs of FIGS. 3A to 3H and 4A to 4H). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 690 includes a processing device 691, a main memory 693 (e.g., read-only memory (ROM), flash memory, dynamic random access memory (DRAM) such as synchronous DRAM (SDRAM) or Rambus DRAM (RDRAM), etc.), a static memory 697 (e.g., flash memory, static random access memory (SRAM), etc.), and a data storage system 698, which communicate with each other via a bus 696.

Processing device 691 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 691 can also be one or more special-purpose processing devices such as an application specific integrated circuit (ASIC), a field programmable gate array (FPGA), a digital signal processor (DSP), network processor, or the like. The processing device 691 is configured to execute instructions 692 for performing the operations and steps discussed herein. The computer system 690 can further include a network interface device 694 to communicate over the network 695.

The data storage system 698 can include a machine-readable storage medium 699 (also known as a computer-readable medium) on which is stored one or more sets of instructions 692 or software embodying any one or more of the methodologies or functions described herein. The instructions 692 can also reside, completely or at least partially, within the main memory 693 and/or within the processing device 691 during execution thereof by the computer system 690, the main memory 693 and the processing device 691 also constituting machine-readable storage media.

In one embodiment, the instructions 692 include instructions to implement functionality corresponding to the crossbar 105 of FIG. 1 and/or the MUXs of FIGS. 3A to 3H and 4A to 4H. While the machine-readable storage medium 699 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
an array of memory cells; and
a crossbar coupled to the array of memory cells and configured to:
couple input lines to the crossbar to output lines from the crossbar in a particular configuration, wherein the output lines couple the crossbar to the array;
receive data values of a matrix via the input lines; and
provide the data values to the array via the output lines, wherein the particular configuration allows the data values provided to the array to be sensed as columns of the data values of the matrix and rows of the data values of the matrix.

2. The apparatus of claim 1, wherein the particular configuration determines an address in the array to which the data values are provided.

3. The apparatus of claim 2, wherein the address in the array to which the data values are provided is different than an address associated with the data values when received via the input lines.

4. The apparatus of claim 1, wherein the particular configuration is one of a plurality of configurations for coupling the input lines to the output lines.

5. The apparatus of claim 4, wherein the crossbar is configured to utilize the plurality of configurations to sense the data values when the apparatus is in a first mode.

6. The apparatus of claim 4, wherein the crossbar is configured to couple the input lines to the crossbar to the output lines of the crossbar in the plurality of configurations.

7. The apparatus of claim 4, wherein each of the plurality of configurations include coupling each of the input lines to a different respective output line.

8. The apparatus of claim 4, wherein each of the plurality of configurations corresponds to a different column of the data values of the matrix.

9. A method, comprising:
coupling input lines to a crossbar of a memory device to output lines of the crossbar in a particular configuration based on a mode of the memory device, wherein the output lines couple the crossbar to input/output (I/O) lines of the memory device and the input lines couple the crossbar to an array of memory cells of the memory device;
receiving data values of a matrix via the input lines; and
providing the data values to the I/O lines, wherein the coupling of the input lines to the output lines in the particular configuration allows the data values provided to the I/O lines to be provided as columns of the data values of the matrix and rows of the data values of the matrix.

10. The method of claim 9, wherein coupling the input lines to the output lines includes coupling the input lines to the output lines in a first configuration based on the mode being a first mode, wherein each of the input lines is coupled to the output lines such that they are offset.

11. The method of claim 10, wherein coupling the input lines to the output lines includes coupling the input lines to the output lines in a second configuration based on the mode being a second mode, wherein each of the input lines is coupled to the output lines in line.

12. The method of claim 11, further comprising updating, using a column decoder of the memory device, an address from which the data values are retrieved from the array responsive to mode being the second mode.

13. The method of claim 12, wherein updating the address from which the data values are retrieved includes updating an address for each multiplexor (MUX) of the memory device that provides signals from sense amplifiers of the memory device to the input lines.

14. The method of claim 13, wherein each MUX is assigned a different address from an adjacent MUX.

15. The method of claim 10, further comprising refraining from updating an address from which the data values are retrieved from the array responsive to the mode being the first mode.

16. An apparatus, comprising:
an array of memory cells;
a number of registers configured to store a mode of the apparatus;
a plurality of multiplexors (MUXs) to couple sense lines of the array to a first plurality of lines that couple the array to a crossbar; and
the crossbar coupled to the number of registers and to the array of memory cells and configured to:
access the mode from the number of registers;
couple the first plurality of lines to a second plurality of lines in a first configuration based on the mode being a first mode and an address associated with the data values, wherein the second plurality of lines couple the crossbar to input/output (I/O) lines of the apparatus;
couple the first plurality of lines to the second plurality of lines in a second configuration based on the mode being a second mode and the address associated with the data values;
receive data values of a matrix via the first plurality of lines;
provide the data values to the I/O lines via the second plurality of lines based on the mode being the first mode or the second mode, wherein the first configuration allows the data values to be sensed as columns of the matrix and the second configuration allows the data values to be sensed as rows of the matrix; and
a column decoder configured to, responsive to the mode being the second mode, configure each of the MUXs differently.

17. The apparatus of claim 16, wherein the crossbar is configured to cause the data values to be stored in the array such that each data value of the columns of the matrix is stored in a different sub-array of the array.

18. The apparatus of claim 16, wherein the crossbar is configured to cause the data values to be stored in the array utilizing a plurality of additional configurations for coupling the first plurality of lines to the second plurality of lines.

19. The apparatus of claim 18, wherein the crossbar is further configured to couple the first plurality of lines to the second plurality of lines in the plurality of additional configurations.

20. The apparatus of claim 19, wherein the crossbar configured to couple the second plurality of lines to the first plurality of lines in a first configuration based on the mode being the first mode is further configured to couple the second plurality of lines to the first plurality of lines in the first plurality of configurations including the first configuration and the second configuration based on the mode being the second mode.
